(19) United States
(12) Patent Application Publication
(10) Pub. No.: US 2006/0289966 A1
(43) Pub. Date: Dec. 28, 2006

(54) Silicon wafer with non-soluble protective coating

(76) Inventors: Ashay A. Dani, Chandler, AZ (US); Gudbjorg H. Oskarsdottir, Reykjavik (IS); James Matayabas JR., Chandler, AZ (US)

Correspondence Address: MARGER JOHNSON & MCCOLLOM, P.C., 210 SW MORRISON STREET, SUITE 400, PORTLAND, OR, 97204, US

(21) Appl. No.: 11/159,515

(22) Filed: Jun. 22, 2005

(51) Int. Cl. H01L 23/58; H01L 21/822

(52) U.S. Cl. 257/620; 438/460; 438/463; 438/958; 257/632; 257/737

(57) ABSTRACT

A silicon wafer with an array of integrated circuit (IC) dies formed on the wafer is provided with a protective coat applied to a surface of the wafer to protect the IC dies from debris created during a laser scribing process. The IC dies can include die bumps that can be adversely affected by debris from the laser scribing process. The protective coat is a tape or a film that may be optically transparent, chemically non-reactive to the laser energy and formed of material that can be ablated by the laser scribing. The protective coat is removed from the IC dies after laser scribing leaving the IC dies and die bumps clean of any debris, thereby decreasing the number of defective dies.

### TECHNICAL FIELD

This disclosure relates to manufacturing integrated circuits from silicon wafers and more specifically to applying a protective coating to the silicon wafer.

### BACKGROUND

Individual integrated circuit dies (or “dice” as they are sometimes called) are typically manufactured by processing a silicon wafer to create a large array of dies on the wafer. After the dies are formed on the silicon wafer, they must be separated from the wafer.

Small abrasive saws can be used to cut the dies from the wafer. However, silicon wafers are brittle, especially wafers utilizing a low-dielectric constant (k) interlayer dielectric. Sawing these brittle silicon wafers can result in chipping along the edges of the saw path or kerf. This tending to chip requires larger spacing between dies, which reduces the number of dies that can be produced on a single wafer.

To help alleviate the need for larger spacing between dies, laser scribing may be used as part of the separating process. A laser creates a groove or other surface discontinuity along a line that may be subsequently sawed (with less chipping due to the smaller thickness being cut) or broken along the line to complete the separation process.

While laser scribing reduces chipping, the scribing tends to produce debris that accumulates on the surface of the silicon wafer adjacent the groove and across the wafer. This debris can cause problems with flip-chip packaging circuits that have an array of solder balls or die bumps created on the surface of the silicon wafer. These die bumps provide an electrical connection to the integrated circuit. This connection is completed by mounting the die onto a substrate and heating the assembly to create soldered connections between the die and the substrate.

Debris from the laser scribing that settles on the die bumps or solder balls prevents the solder from properly wetting during the process of attaching the silicon chip to the substrate. Debris can further contaminate other portions of the die. This failure to properly wet and the potential contamination may result in a defective device.

As a result, when laser scribing is used to separate dies from a silicon wafer, all debris from the laser scribing process should be removed from the silicon wafer prior to the packaging of the dies.

### BRIEF DESCRIPTION OF THE DRAWINGS

The description may be best understood by reading the disclosure with reference to the accompanying drawings.

FIG. 1 is a top plan pictorial depiction of a silicon wafer with an array of integrated circuits formed on the wafer according to an embodiment of the invention.

FIG. 2 is a cross-sectional view of the silicon wafer of FIG. 1 taken along line A-A.

FIG. 3 is a cross-sectional view of the silicon wafer of FIG. 1 taken along line A-A after a laser scribing process has been performed.

FIG. 4 is a cross-sectional view of the silicon wafer of FIG. 1 taken along line A-A after a laser scribing process showing a protective coat being removed.

### DETAILED DESCRIPTION

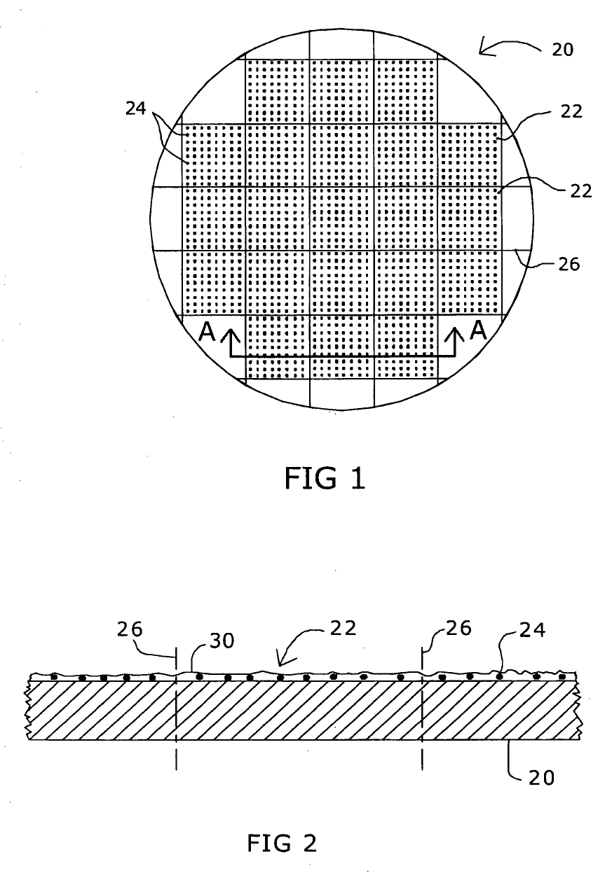

FIG. 1 shows a top plan pictorial view of a silicon wafer 20 according to an embodiment of the invention. The silicon wafer 20 includes an array of integrated circuit (IC) dies 22. In this embodiment, the IC dies 22 include die bumps 24 coupled to an active surface of each IC die. The die bumps 24 are raised bumps of solder for subsequently connecting a die to a substrate (not shown) in a package. The dies 22 will be separated from the wafer 20 along lines 26.

The wafer 20 and IC dies 22 are not shown to scale for illustration purposes. A typical silicon wafer 20 will have many more IC dies 22 formed on the wafer 20 than is shown in FIG. 1. The number of die bumps 24 per die 22 can also vary depending the type of IC die 22. It is contemplated that embodiments of the invention include dies 22 that utilize types of terminations other than die bumps 24. The wafer 20 can include IC dies 22 that are formed with a low dielectric constant (k) interlayer dielectric which can make the wafer 20 brittle thereby making laser scribing useful.

FIG. 2 shows a cross-sectional view of the silicon Wafer 20 taken along line A-A in FIG. 1. A removable, non-soluble protective coat 30 is shown applied to the surface of the silicon wafer 20 over the dies 22 and die bumps 24. The protective coat 30 may conform to the surface of the wafer 20 and the die bumps 24.

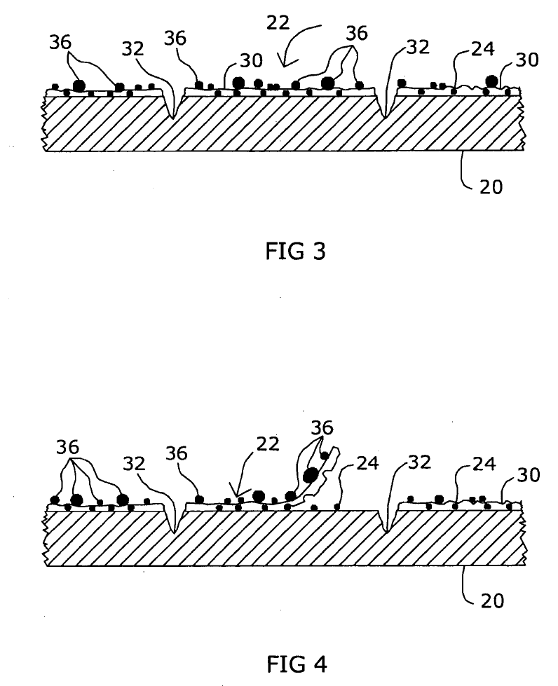

The protective coat 30 protects the IC die 22 and the die bumps 24 from debris 36 (see FIGS. 3 and 4) that is created when the silicon wafer 20 is laser scribed for separating the dies 22 from the wafer 20. After laser scribing cuts grooves 32 (see FIGS. 3 and 4) along lines 26, the protective coat 30 can then be removed from the die 22 for completion of the packaging process.

The protective coat 30 may be a tape or a film formed from materials such as polyimides, polyvinyl alcohol, methyl cellulose, household transparent tape, PET (polyester), photoresist and soy protein. Certain characteristics of the protective coat 30 can help the protective coat effectively protect the dies 22 and die bumps 24. The protective coat 30 may be optically transparent for the visual and fiducial alignment in the laser scribing process and any potentially subsequent saw processes. The protective coat 30 may also be ablated during the laser scribe process and may be chemically non-interactive with laser energy.

FIG. 3 shows the cross-sectional view of FIG. 2 after a laser scribing process is performed on wafer 20. Grooves 32 have been cut into the wafer 20 along lines 26. Debris 36 from the laser scribing process has been deposited onto the protective coat 30 which keeps the debris 36 from contaminating the IC dies 22 and die bumps 24. Here, the protective coat 30 has been ablated by the laser scribing process.

FIG. 4 shows the cross-sectional view of FIGS. 2 and 3 showing the protective coat 30 being peeled from the IC die 22 leaving the IC die 22 and die bumps 24 clean. Removing the protective coat 30 can include peeling or washing the protective coat 30 off of the dies 22 with water or a chemical solvent. In the case of using solvent to wash the protective coat 30, the solvent physically washes the protective coat 30 off of the dies 22 and does not dissolve the protective coat. It is contemplated that the protective coat 30 can be removed from the dies 22 either before or after the dies are separated from the silicon wafer 20.

The preceding embodiments are exemplary. Those of skill in the art will recognize that the concepts taught herein can be tailored to a particular application in many other advantageous ways. In particular, those skilled in the art will recognize that the illustrated embodiments are but one of many alternative implementations that will become apparent upon reading this disclosure.

Although the specification may refer to “an”, “one”, “another”, or “some” embodiment(s) in several locations, this does not necessarily mean that each such reference is to the same embodiment(s), or that the feature only applies to a single embodiment.

What is claimed is:

1. A silicon wafer, comprising:
an array of integrated circuits arranged on a first surface of the silicon wafer; and
a removable non-soluble protective coat on the first surface of the silicon wafer.

2. The silicon wafer of claim 1, comprising die bumps coupled to an active surface of each integrated circuit, where the non-soluble protective coat covers the die bumps.

3. The silicon wafer of claim 2 where the removable non-soluble protective coat conforms to the wafer surface and die bumps.

4. The silicon wafer of claim 1 where the removable non-soluble protective coat is one of a film and a tape.

5. The silicon wafer of claim 1 where the removable non-soluble protective coat is one of a polyimide, polyvinyl alcohol, household transparent tape, and polyester.

6. The silicon wafer of claim 1 where the removable non-soluble protective coat is removable by peeling the coat from the first surface of the silicon wafer.

7. The silicon wafer of claim 1 where the removable non-soluble protective coat is optically transparent.

8. The silicon wafer of claim 1 where the removable non-soluble protective coat is formed of a material that is non-chemically interactive with laser scribing.

9. The silicon wafer of claim 1 where the removable non-soluble protective coat is formed of a material that can be ablated by laser energy.

10. The silicon wafer of claim 1 where the silicon wafer has a low dielectric constant.

11. A silicon wafer, comprising:
an array of integrated circuits arranged on a first surface of the silicon wafer; and
a non-soluble means for protecting the integrated circuits from debris produced by a laser scribing process.

12. The silicon wafer of claim 11 where the integrated circuits include die bumps coupled to an active surface of each integrated circuit; and
the non-soluble means for protecting the integrated circuits protects the die bumps from debris produced by a laser scribing process.

13. The silicon wafer of claim 11 where the non-soluble means for protecting the integrated circuits is optically transparent.

14. The silicon wafer of claim 11 where the integrated circuits include a low dielectric constant (k) interlayer dielectric.

15. A method for manufacturing an integrated circuit die, comprising:
forming an array of integrated circuit dies on a first surface of a silicon wafer;
applying a non-soluble protective coat to the first surface of the silicon wafer;
laser scribing a groove next to a row of integrated circuit dies;
removing the non-soluble protective coat from the first surface of the silicon wafer; and
separating an integrated circuit die from the silicon wafer.

16. The method of claim 15 where forming an array of integrated circuit dies on a first surface of a silicon wafer includes forming die bumps coupled to each of the integrated circuits.

17. The method of claim 15 where forming an array of integrated circuit dies includes forming a low dielectric constant (k) interlayer dielectric.

18. The method of claim 15 where removing the non-soluble protective coat from the first surface of the silicon wafer includes peeling the non-soluble protective coat from the first surface of the silicon wafer.

19. The method of claim 15 where laser scribing a groove includes ablating the non-soluble protective coat.
